(19) United States
(12) Patent Application Publication
(10) Pub. No.: US 2005/0205865 A1
(43) Pub. Date: Sep. 22, 2005

(54) IC testing apparatus and methods

(76) Inventors: Hang-Dony Kuan, Plano, TX (US); Yingsheng Tung, Plano, TX (US)

Correspondence Address: TEXAS INSTRUMENTS INCORPORATED, P O BOX 655474, M/S 3999, DALLAS, TX, 75265, US

(21) Appl. No.: 10/804,374

(22) Filed: Mar. 19, 2004

(51) Int. Cl. H01L 23/58; G01R 31/02

(52) U.S. Cl. 257/48; 324/765

(57) ABSTRACT

Methods, devices, and systems of the invention provide improved semiconductor device testing with firm tester-to-device interface and increased contact area. A test probe (24, 58) associated with ATE (18) is configured to substantially correspond to a probe receptacle (38) of a test board (16) or semiconductor device (10). Upon insertion of the test probe (24, 58) into the probe receptacle (38), areas of staunch electrical contact (34) between the probe receptacle (38) and probe (24, 58) facilitate measuring an electrical signal.

### TECHNICAL FIELD

The invention relates to semiconductor device and integrated circuit (IC) testing. More particularly, it relates to new testing apparatus and methods for testing semiconductor devices.

### BACKGROUND OF THE INVENTION

Semiconductor devices such as ICs are often subject to testing. It is known to test wafers containing numerous semiconductor devices or to test singulated devices. These types of testing present many technical challenges in order to adequately verify the operation of the device under test (DUT), and simultaneously to minimize false readings due to the test conditions. Poor electrical contact, often due to insufficient contact area, can result in erroneous test readings indicative of parasitic contact resistance or inductance, short circuits, reduced output amplitude, or other problems. Such erroneous readings can lead to the rejection of serviceable devices, resulting in the reduction of perceived yields, leading in turn to increased costs.

Commonly, probe testing is carried out using automatic test equipment (ATE) configured for verifying the proper functioning of semiconductor devices before they are completed. In general, probes associated with the ATE are placed in electrical contact with metallized contact surfaces, such as test or bond pads, of a semiconductor die. The functioning of the die may be tested by measuring various inputs and outputs at the metallized bond pads. One of the problems encountered in this type of testing is ensuring adequate electrical contact between the test probes of the ATE and the contact surfaces of the DUT.

Final testing of singulated devices is often performed using automatic test equipment (ATE) interfaced with a device under test (DUT). Generally a printed circuit board (PCB), or test board, is electrically connected to the ATE, where inputs and outputs may be measured to verify the operation of the DUT. The interface between the ATE and DUT conventionally includes a socket for securely mounting the DUT. A DUT, such as a BGA, for example, is placed in the socket and secured. Contact points on the DUT, such as solder balls in the case of a BGA, make contact with test probes or pins, such as pogo pins or probe contacts on a probe membrane. The pins in turn make contact with the test board. A problem in the arts is ensuring adequate electrical contact between the pins and metal contact areas on the surface of the test board.

Problems caused by insufficient probe-to-device or probe-to-PCB contact can be particularly acute when testing high-frequency devices. Devices operated and tested at high frequencies require firm electrical contact over a sufficient area due to increased edge effects in the conductive couplings, often called “skin effect”. Insufficient or feeble contact between the contact surfaces on a DUT and test probes can lead to spurious results. Due to these and other problems, it would be useful and advantageous to provide apparatus and methods for testing semiconductor devices using improved electrical contact between test equipment and tested devices, particularly at the interface between the test board and DUT.

### SUMMARY OF THE INVENTION

In carrying out the principles of the present invention, in accordance with preferred embodiments thereof, methods, systems, and devices of the invention provide semiconductor device testing with staunch electrical contacts at the interface between tester and device.

According to one aspect of the invention, methods for testing a semiconductor device include a step of providing a pin receptacle in a test board. The test board is aligned with the device and a pin is interposed between the pin receptacle and a contact surface of the device. The pin makes staunch electrical contact between the contact surface of the device and the pin receptacle of the test board for measuring an electrical signal in the device.

According to one aspect of the invention, a preferred embodiment includes a test board for use in association with semiconductor device automatic test equipment (ATE). A socket is further associated with the ATE. The socket has pins and is adapted for receiving and securing a device under test (DUT). The preferred embodiment of the test board includes a contact point for operably coupling a pin to the ATE. A pin receptacle on the contact point is configured for receiving the pin, thereby ensuring staunch electrical contact between the pin and contact point.

According to an additional aspect of the invention, a system for probe testing a semiconductor device includes a socket for receiving a device under test (DUT). The socket has pins for making contact between the DUT and a test board. A contact surface on the test board includes pin receptacles for receiving the pins. Measuring means are operably coupled to the test board pin receptacles for measuring electrical signals in the DUT.

According to yet another aspect of the invention, methods, apparatus and systems of the invention are embodied with an RF membrane probe for making staunch electrical contact with a probe receptacle on an IC.

According to still another aspect of the invention, the invention is embodied in a semiconductor device having external contact surfaces with probe receptacles situated on the contact surfaces. The probe receptacles are adapted for receiving test probes associated with test equipment.

Preferred embodiments of the invention are disclosed in which the probe receptacles are constructed by patterning and etching techniques, precision drilling, or metal deposition.

The invention provides technological advantages including but not limited to improved testing reliability, particularly for high-frequency applications. Preferred embodiments of the invention also provide additional advantages by being amenable to common manufacturing and testing processes, resulting in lowered costs. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top perspective overview of examples of preferred embodiments of methods, systems, and devices of the invention;

FIG. 2 is a cut away partial side view illustrating preferred embodiments of the invention;

FIG. 3 is a cut away partial side view of an example of a partially assembled test board for use with preferred embodiments of the invention;

FIG. 4 is a cut away partial side view of the test board of FIG. 3 showing an additional stage in assembly;

FIG. 5 is a cut away partial side view of the test board of FIG. 4 showing a further stage in assembly;

FIG. 6 is a cut away partial side view of an example of a test board illustrating a preferred embodiment of the invention;

FIG. 7 is a partial cut away top view of the example of the preferred embodiment of the invention shown in FIG. 6;

FIG. 8 is a cut away partial side view of an example of a partially assembled test board for use with an alternative embodiment of the invention;

FIG. 9 is a cut away partial side view of the test board of FIG. 8 showing an additional stage in assembly;

FIG. 10 is a cut away partial side view of the test board of FIG. 9 showing a further stage in assembly;

FIG. 11 is a cut away partial side view of an example of a test board illustrating an alternative embodiment of the invention;

FIG. 12 is a partial cut away top view of the example of the alternative embodiment of the invention shown in FIG. 11; and

FIG. 13 is a partial cut away side view of an example of a semiconductor device using a preferred embodiment of the invention.

References in the detailed description correspond to the references in the figures unless otherwise noted. Descriptive and directional terms used in the written description such as first, second, top, bottom, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the methods and apparatus of the invention provide improved reliability for testing of semiconductor devices. Staunch electrical contact is ensured between IC or PCB contact points and test probes.

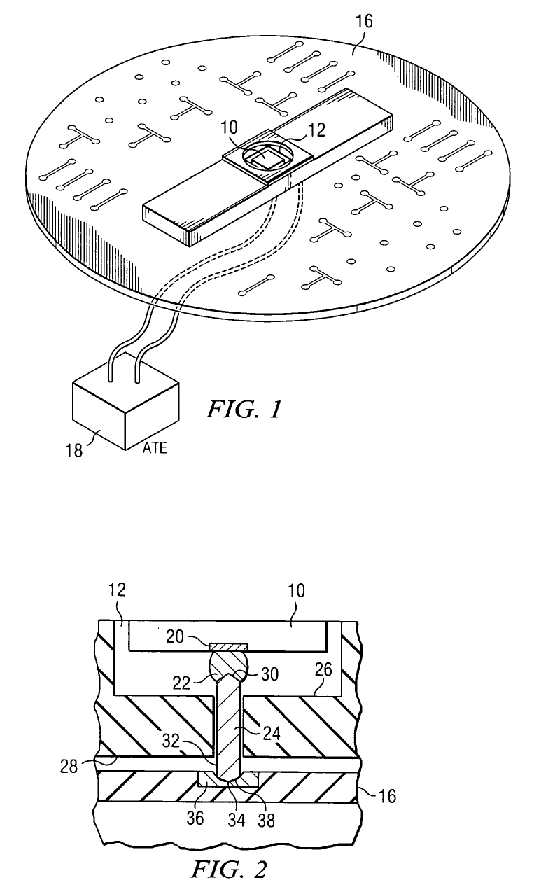

First referring primarily to FIG. 1, an overview of examples of preferred embodiments of methods, systems, and apparatus of the invention is provided. A DUT 10 is shown. The DUT 10 may be a packaged semiconductor device, such as a surface-mount BGA, for example. The DUT 10 is preferably mounted in a socket 12. The socket 12 is positioned on a PCB test board 16 designed to interface with automatic test equipment (ATE) 18. Further referring to FIG. 2, a close-up partial cross-section is shown. The DUT 10 has a contact surface 20, in this case a bond pad 20 with a solder ball 22 attached. A test probe, in this instance a pogo pin 24, extends from the upper surface 26 of the socket 12 to the lower surface 28. The pin 24 functions as an electrical path between the DUT 10 and the test board 16. As shown, the upper tip 30 of the pin 24 contacts the solder ball 22. It is known that the solder ball 22 is relatively soft metal such as a mixture of various amounts of lead, tin, and silver. As a result, the solder ball 22 has a tendency to conform somewhat to the upper tip 30 of the pin. Thus, the contact between the solder ball 22 and the top 30 of the pin 24 is generally sufficient in area and firmness in order to provide a reliable electrical path.

At the opposing end 32 of the pin 24, contact 34 is made with a contact area 36 on the test board 16. The contact area 36 is typically metal, often multiple layers, including copper, nickel, or gold. The contact area 36 has a probe or pin receptacle 38 for receiving the bottom tip 32 of the pin 24 in order to ensure staunch electrical contact 34 between the pin 24 and the contact area 36 on the test board 16. The total area of contact 34 is increased by the correspondence of the pin tip 32 and the pin receptacle 38. The contact area 36 of the test board 16 is connected to the ATE (not shown) for making test measurements as is common in the arts. The electrical path between the DUT 10 and the ATE includes the staunch contact 34 between the pin 24 and pin receptacle 38 through which accurate measurements may be made. It has been found that a superior electrical path is provided using the receptacle 38 and pin 24 arrangement, particularly when operating at the high frequencies of modern RF devices.

Many alternative configurations are possible without departure from the invention as long as corresponding probe tips 32 and receptacles 38 are used to ensure staunch electrical contact 34. For example, the probe receptacle 38 and pin tip 32 may be generally conical, hemispherical, or other shapes. Preferably, the receptacles 38 are drilled into the contact areas 36 of the test board 16 using precision laser or mechanical drilling techniques. In an example of another alternative embodiment, probe membrane structures known in the arts may be substituted for the pogo pin arrangement shown and described. An additional example of an alternative embodiment of the invention may be used in the context of probe testing semiconductor devices on a wafer before singulation and packaging. As further described, probe receptacles may be formed in contact surfaces during the manufacture of a test board or device using common etching and deposition techniques.

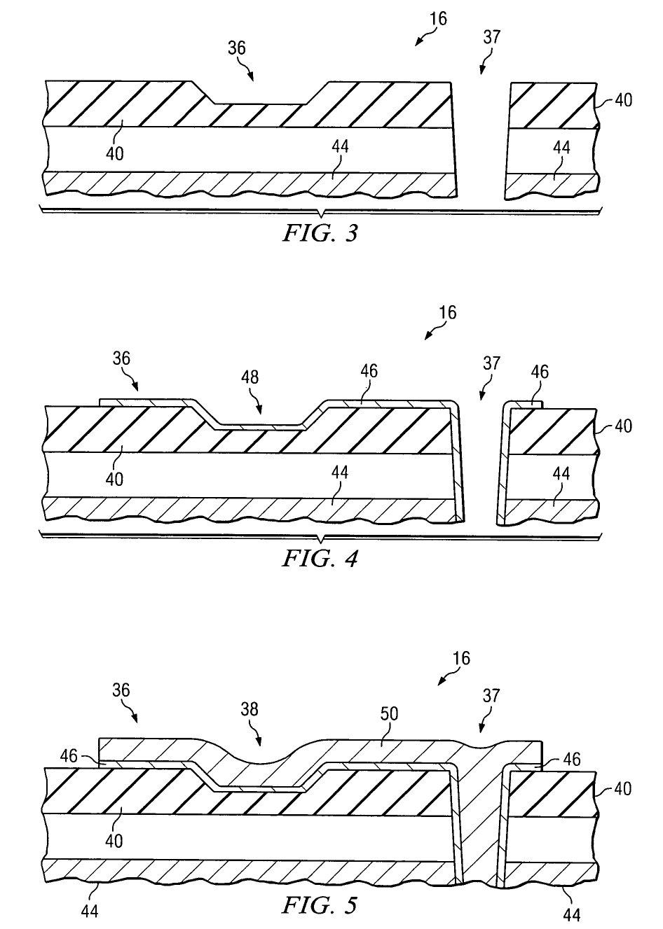

Now referring primarily to FIG. 3, another example of preferred embodiments of the invention is shown beginning with a cross section view of a portion of a partially assembled test board 16. The PCB 16 includes a top layer 40, which may be a layer of insulating material, such as RF-4, a registered trademark of Texas Instruments Incorporated. The board 16 also has contact areas 36 used for making electrical connections externally to a DUT and ATE. The contact areas 36 are electrically connected to other layers 44 or portions of the test board 16 internally or to ground (not shown). Typically vias 37 are used to make electrical connections among layers of the PCB 16, such as between a contact area 36 at the surface and one or more subsurface layer 44. Generally, a test board 16 has numerous contact areas 36 designed to make the ATE operative when coupled to various external inputs and outputs of a DUT (not shown). Many configurations of test board 16 are possible and may be used without departure from the scope of the invention as long as a contact area 36 is provided.

It is known to deposit conductive metals or combinations of metal such as copper, nickel, tin, or gold, for example, in one or more layers to construct test pads 36 or bond pads (20 FIG. 2) at selected locations on a device (10 FIG. 2) or PCB 16. Referring to FIG. 4, a contact area 36 is shown overlain by a first metal layer 46. Preferably, the first metal layer 46 is formed to define the contact area 36 in such a way as to form a basin 48 at the top surface of the layer 46. A second metal layer 50 is preferably formed atop the first metal layer 46, as depicted in FIG. 5. Although two metal layers 46, 50, are shown in this example, it should be understood by those skilled in the arts that the layering steps may be performed any number of times depending upon the design of the PCB 16. The layering steps are preferably repeated until a multilayer structure is constructed with a probe receptacle 38 as shown. It should be appreciated that the formation of the receptacle 38 may be performed concurrently with the formation of a conductive path among layers (e.g., 36, 44) through the filling of a via 37. Preferably, the steps in the construction of the probe receptacle 38 are included in standard semiconductor manufacturing processes used to manufacture the PCB 16. Preferably, the shape of the probe receptacle 38 is manipulated by adjusting the preparation of the contact area 36 and surrounding material 40 prior to the addition of further metallic layers, e.g.; 46, 50. When completed, the successive basins e.g.; 48, in the layers form a probe or pin receptacle 38 atop the contact area 36.

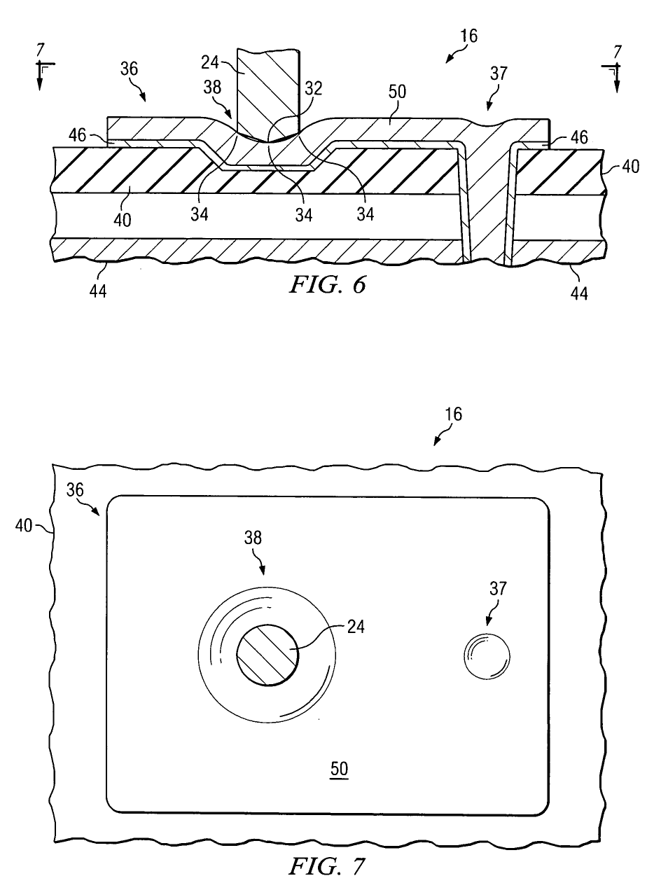

Now referring primarily to FIG. 6, a partial cross section showing an example of an embodiment of a test board 16 constructed according to the invention is illustrated. The test board 16 shown may be constructed with a receptacle 38 by layering as described. Alternatively, a test board 16 with a completed contact area 36 may be drilled using precision drilling equipment to form a receptacle 38. A test probe, or pin 24, inserted into the pin receptacle 38 of a multilayer contact area 36 is shown. The test pin 24 is preferably generally conical or hemispherical at its lower tip 32 in order to facilitate substantial areas of firm contact 34 between the surface of the pin receptacle 38 and the tip 32 of the test pin 24.

Understanding of the invention may be enhanced by reference to FIG. 7, which shows a top view of the test board 16 of FIG. 6 with the pin 24 cut away at line 7-7. The pin 24 may be seen inserted into the receptacle 38 of the contact area 36 for making firm electrical contact between the test board 16 and the pin 24, which through the conductor-filled via 37, is in turn electrically connected to the ATE and DUT (not shown). It should be appreciated by those skilled in the arts that alternative techniques may be used for the formation of the pin receptacle 38 on the contact area 36, such as for example, precision drilling, or patterning and etching a basin into a prepared substantially flat contact area. In this way, conventional test boards may be modified for use according to the invention, preferably by laser drilling, for example. Other alternative embodiments are possible and could include, for example, generally cylindrical test probe tips and corresponding cylindrical-walled probe receptacles. These examples and other alternative embodiments approaches may be used without departure from the invention so long as staunch contact between the test probe and the contact area are provided.

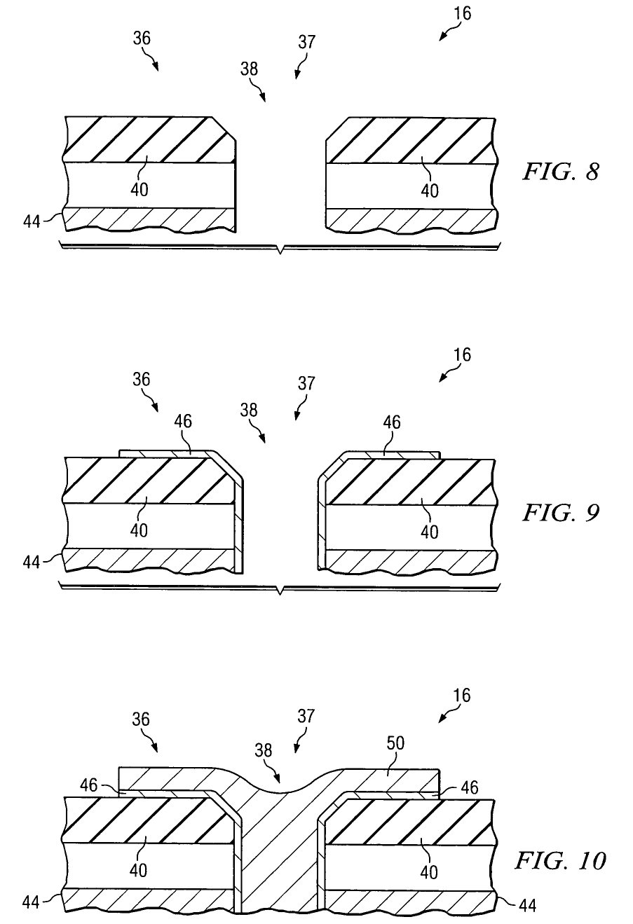

An alternative embodiment of the invention, is shown in FIGS. 8-12, demonstrating that a pin receptacle 38 may be formed atop a via 37 on the test board 16. As shown in FIG. 8, a cross section view of a portion of a partially assembled test board 16, the PCB 16 includes a top layer 40 of non-conducting material. The board 16 also has contact areas 36 used for making electrical connections externally to a DUT and ATE. The contact areas 36 are electrically connected to other layers 44 or portions of the test board 16 internally or to ground (not shown). A via 37 is used to form electrical connections among two or more layers of the PCB 16, such as between a contact area 36 at the surface and one or more subsurface layer 44. Referring to FIG. 9, the contact area 36 is shown overlain by a first metal layer 46. The first metal layer 46 is formed to define a contact area 36, preferably more or less centered on the via 37. Many configurations of test board 16 are possible and may be used without departure from the scope of the invention as long as a contact area 36 encompassing the via 37 is provided. The first metal layer 46 is preferably deposited within the via 37 as well. A second metal layer 50 is preferably formed atop the first metal layer 46, as depicted in FIG. 10, covering the contact area and substantially filling the via 37. Although only two metal layers 46, 50, are shown for the purposes of this example, the layering steps may be performed to provide more numerous layers. The layering steps are preferably repeated until a multilayer structure is constructed with a probe receptacle 38 as shown. Accordingly, the formation of the receptacle 38 may be performed concurrently with the formation of a conductive path among layers (e.g., 36, 44) through the filling of a via 37.

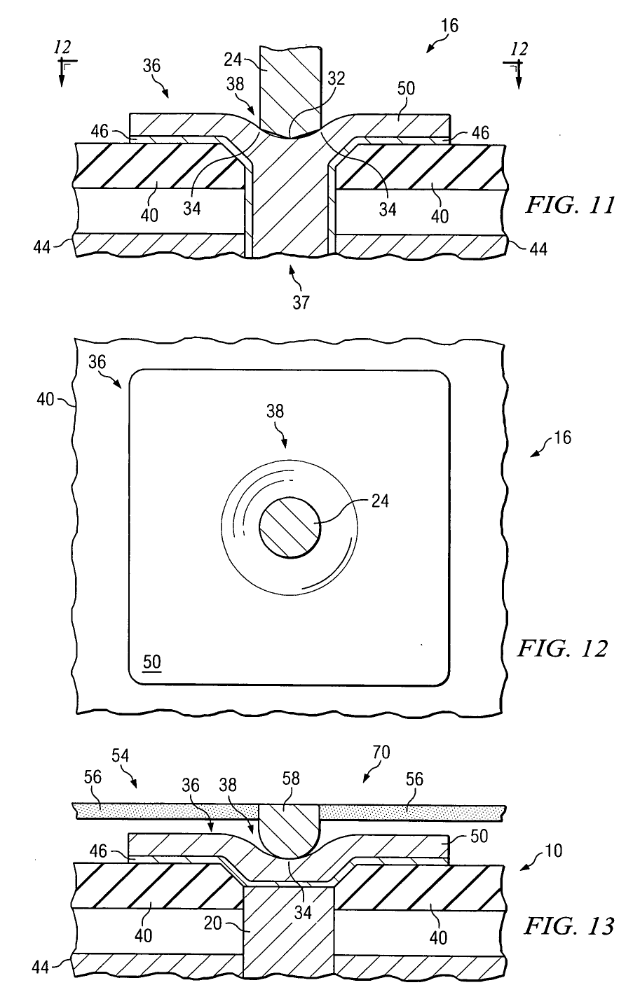

Now referring primarily to FIG. 11, a partial cross section showing an example of an embodiment of a test board 16 constructed according to the invention is illustrated with a test pin 24 inserted into the pin receptacle 38 of a multilayer contact area 36 is shown. The test pin 24 is preferably generally conical or hemispherical at its lower tip 32 in order to facilitate substantial areas of firm contact 34 between the surface of the pin receptacle 38 and the tip 32 of the test pin 24.

An alternative view of the invention appears in FIG. 12, showing a partial cut-away top view of the test board 16 according to the embodiment of the invention shown in FIG. 11 with the pin 24 cut away at line 12-12. The pin 24 is shown inserted into the receptacle 38 of the contact area 36 for making firm electrical contact between the test board 16 and the pin 24. The pin 24, through the conductor-filled via 37, is in turn electrically connected to the ATE and DUT (not shown).

FIG. 13 is a partial cross section representative of an example of alternative embodiments of the invention providing a pin receptacle 38 in a semiconductor device 10. For the purposes of making electrical connections for input and output, the structure of a semiconductor device 10 is similar to that described for a PCB. A contact surface 36, such as a bond or test pad 20, is shown with a probe receptacle 38, preferably formed during the manufacturing processes. An RF probe membrane 54 has a membrane 56 with embedded test probes 58 for making electrical contact 34 with the bond pad 36. The probe receptacle 38 of the pad 36 is configured to accept the probe 58 in order to provide firm contact 34 with a relatively large area of the probe 58. In this way, firm contact sufficient for reliable testing, such as high frequency testing for RF devices using frequencies in excess of 1 GHz, is provided. Of course, semiconductor devices 10 using the invention may also be embodied in applications using a pogo pin arrangement as well.

Thus, the invention provides improved semiconductor testing apparatus and methods using test probes with corresponding probe receptacles configured for firm electrical contact between testing equipment and tested devices. While the invention is described with reference to certain illustrative embodiments, the methods and apparatus described are not intended to be construed in a limited sense. Various modifications and combinations of the illustrative embodiments as well as other advantages and embodiments of the invention will be apparent to persons skilled in the art upon reference to the description and claims.

1. A method for testing a semiconductor device comprising the steps of:
providing a pin receptacle in a test board adjacent to a contact surface of the device;
interposing a pin between the pin receptacle and the contact surface of the device, the pin thereby making electrical contact between the contact surface of the device and the pin receptacle of the test pad; and
measuring an electrical signal in the device using the electrical contact between the pin receptacle and pin.

2. A method according to claim 1 wherein the step of measuring further comprises the step of measuring an electrical signal having a frequency greater than 1 GHz.

3. A method according to claim 1 wherein the step of providing a pin receptacle further comprises the step of drilling the test board.

4. A method according to claim 1 wherein the step of providing a pin receptacle further comprises the step of etching the test board.

5. A method according to claim 1 wherein the step of providing a pin receptacle further comprises the step of depositing a metal layer on the test board.

6. A system for testing a singulated semiconductor device (DUT) comprising:
a socket for receiving a DUT, the socket having pins with ends for making electrical contact with the DUT and opposing ends for making contact with a test board;
a test board adjoining the socket, the test board having pin receptacles for receiving the opposing ends of the pins; and
measuring means operably coupled to the test board pin receptacles for measuring electrical signals in the DUT.

7. A system according to claim 6 wherein the receptacles each further comprise a basin for receiving the pin.

8. A system according to claim 6 wherein the receptacles each further comprise a generally conical basin for receiving the pin.

9. A system according to claim 6 wherein the receptacles each further comprise a generally hemispherical basin for receiving the pin.

10. A system according to claim 6 wherein the receptacles each further comprise a precision drilled basin.

11. A system according to claim 6 wherein the receptacles each further comprise an etched basin.

12. A test board for use in association with semiconductor device automatic test equipment (ATE) and a socket, the socket having pins and adapted for receiving a device under test (DUT), the test board comprising:
a contact area for operably coupling a pin to the ATE;
a pin receptacle on the contact area for receiving a pin, for thereby making staunch electrical contact between the pin and contact point.

13. A test board according to claim 12 wherein the pin receptacle further comprises a basin for receiving the pin.

14. A test board according to claim 12 wherein the pin receptacle further comprises a generally conical basin for receiving the pin.

15. A test board according to claim 12 wherein the pin receptacle further comprises a generally hemispherical basin for receiving the pin.

16. A method for probe testing a semiconductor device comprising the steps of:
providing a probe receptacle at a contact surface on the semiconductor device;
inserting a probe into the probe receptacle, thereby making electrical contact between the probe receptacle and probe; and
measuring an electrical signal in the device using the electrical contact between the probe receptacle and probe.

17. A semiconductor device comprising:
a plurality of contact surfaces; and
a probe receptacle situated on each of a plurality of the contact surfaces, each probe receptacle adapted for receiving a test probe.

18. The semiconductor device according to claim 17 wherein the probe receptacles further comprise deposited basins.

19. The semiconductor device according to claim 17 wherein the probe receptacles further comprise etched basins.
